(19) United States
(12) Patent Application Publication
(10) Pub. No.: US 2015/0001726 A1
(43) Pub. Date: Jan. 1, 2015

(54) POWER SEMICONDUCTOR MODULE

(71) Applicant: Samsung Electronics Co., Ltd., Suwon-Si (KR)

(72) Inventors: Baik-woo LEE, Gwangmyeong-si (KR); Seong-woon BOOH, Yongin-si (KR)

(73) Assignee: Samsung Electronics Co., Ltd., Suwon-Si (KR)

(21) Appl. No.: 14/087,472

(22) Filed: Nov. 22, 2013

(30) Foreign Application Priority Data
Jun. 28, 2013 (KR) 10-2013-0075413

(51) Int. Cl. H01L 29/45; H01L 27/04

(52) U.S. Cl. CPC H01L 29/45; H01L 27/04
USPC 257/762

(57) ABSTRACT

A power semiconductor module includes a first power device on a substrate, a first electrode on an upper surface of the first power device, a first nickel plating layer on the first electrode, and a copper wire connected to the first nickel plating layer.

### CROSS-REFERENCE TO RELATED APPLICATIONS

This application claims the benefit of Korean Patent Application No. 10-2013-0075413, filed on Jun. 28, 2013, in the Korean Intellectual Property Office, the disclosure of which is incorporated herein in its entirety by reference.

### BACKGROUND

1. Field

Some example embodiments relate to power semiconductor modules that include an electrode reinforcement nickel plating layer for a copper wire bonding.

2. Description of the Related Art

In an inverter circuit of an industrial motor or a motor of a vehicle, a power supply device of a large capacity server, and an uninterruptible power supply, in order to handle a relatively large power, a power semiconductor device in a range from a few KW to a few MW is used. A semiconductor switch such as a metal-oxide-semiconductor field-effect transistor (MOSFET) or an insulated gate bipolar transistor (IGBT) is used as the power semiconductor devices.

A power module includes a power device attached to a substrate, and the power device is electrically connected to another device or a pad on the substrate.

The electrical connection of the power module includes an electrical interconnection between power device (IGBT, MOSFET, diode) and power device or an electrical interconnection between power device and substrate, and an aluminum wire bonding is widely used for the electrical interconnections.

In a recent power module, the power density of the power module has been increased as a higher current power device is used having a small size. Accordingly, a large amount of heat is generated from the power module. Also, a power module consisting of power devices, such as GaN and SiC that are operated at a high temperature draws attention. There is a need to study about an electrical interconnection that connects power device to power device or power device to substrate which can be operated at a high temperature to correspond to the trend of high power density and high temperature operation power module. In case of the Al wire bonding which is a generally used for power module, the melting point of Al is about 660° C., and a homologous temperature at an operating temperature of 200° C. corresponds to 0.5 which means sensitive to creep.

### SUMMARY

Some example embodiments provide power semiconductor modules that include a nickel plating layer for an electrode reinforcement in using a Cu wire having a higher melting point than a conventional Al wire, and are able to be operated at a relatively high temperature.

Additional aspects will be set forth in part in the description which follows and, in part, will be apparent from the description, or may be learned by practice of the presented embodiments.

According to an example embodiment, a power semiconductor module includes a first power device on a substrate, a first electrode on an upper surface of the first power device, a first nickel plating layer on the first electrode, and a copper wire connected to the first nickel plating layer.

The first electrode may be formed of one of aluminum and an aluminum alloy. The power semiconductor module may further include an electrode pad separate from the first power device on the substrate, wherein the copper wire may be connected to the electrode pad. The substrate may be one of a direct bonded copper (DBC) substrate, a lead frame substrate, and a printed circuit board (PCB). The first power device may include at least one of an metal-oxide-semiconductor field-effect transistor (MOSFET), an insulated gate bipolar transistor (IGBT), and a diode.

The power semiconductor module may further include a second power device on the substrate, the second power device including one of an MOSFET, an IGBT, and a diode, a second electrode on an upper surface of the second power device, and a second nickel plating layer on the second electrode, wherein the copper wire connects the first nickel plating layer on the first electrode and the second nickel plating layer on the second electrode.

The first nickel plating layer may have a thickness in a range from about 3 μm to about 30 μm. The first nickel plating layer may include one of phosphorus and boron. The first nickel plating layer may be formed of one of nano grains and an amorphous layer. The power semiconductor module may further include a protection layer surrounding sides of the first power device. The protection layer may include one of polymer resist, silicon oxide, and silicon nitride. The copper wire may have a diameter in a range from about 100 μm to about 500 μm. The copper wire may form a line contact with the first nickel plating layer by being connected to the first nickel plating layer using a wedge bonding.

### BRIEF DESCRIPTION OF THE DRAWINGS

These and/or other aspects will become apparent and more readily appreciated from the following description of the embodiments, taken in conjunction with the accompanying drawings of which:

FIG. 1 is a schematic cross-sectional view of a structure of a power semiconductor module according to an example embodiment;

FIG. 2 is a schematic plan view of the structure of the power semiconductor module of FIG. 1; and

FIG. 3 is a schematic plan view of a structure of a power semiconductor module according to an example embodiment.

### DETAILED DESCRIPTION

Hereafter, the inventive concepts will be described more fully with reference to the accompanying drawings, in which some example embodiments are shown. In the drawings, like reference numerals refer to the like elements throughout, and constituent elements having like reference numeral may be formed of the same material. Also, sizes of the constituent elements may be exaggerated for clarity and explanation.

The embodiments described below are examples and may be embodied in many different forms. For example, it will be understood that when an element is referred to as being “on” or “above” another element, it may be directly on or above the other element, or intervening elements may also be present.

Also, spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

In the current specification, the term “layer” is used to describe a portion of a structure formed by folding objects. Accordingly, the term “layer” should not be construed as limited to the thickness of the object.

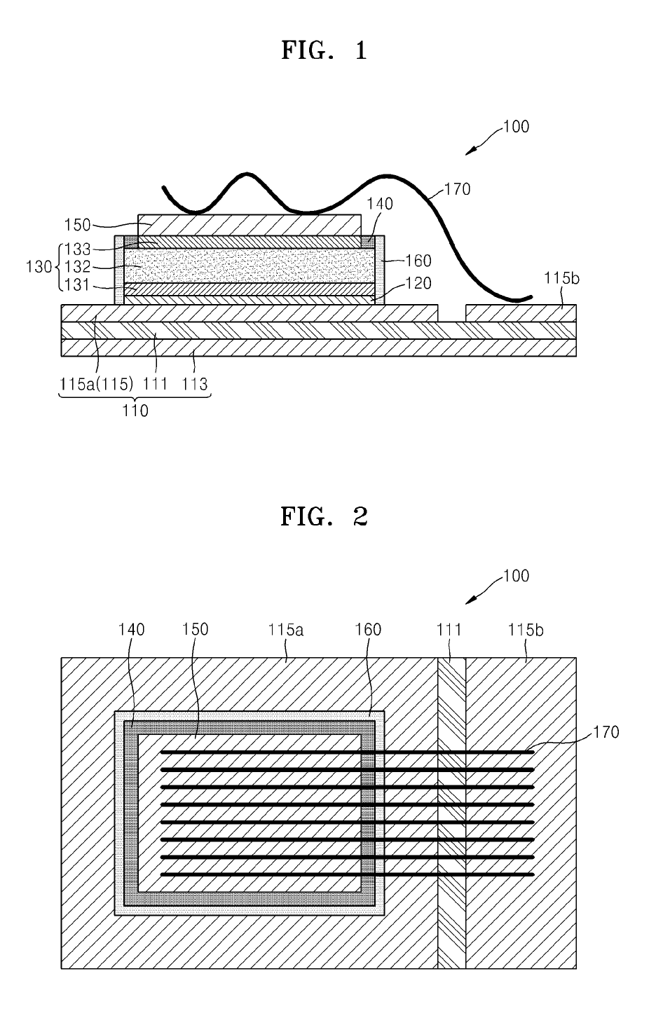

FIG. 1 is a schematic cross-sectional view of a structure of a power semiconductor module 100 according to an example embodiment.

Referring to FIG. 1, a power device 130 is bonded on a substrate 110. A plurality of power devices 130 may be disposed on the substrate 110. However, in FIGS. 1 and 2, for convenience of explanation, a single power device 130 is disposed on the substrate 110.

The power device 130 may include a lower electrode 131, a semiconductor layer 132, and an upper electrode 133. The lower electrode 131 may be bonded to the substrate 110 having a solder layer 120 therebetween. The power device 130 generally includes two electrodes or three electrodes. In FIG. 1, for convenience of explanation, the power device 130 includes an electrode on an upper surface and a lower surface of the power device 130 respectively. An electroless nickel plating layer 150 is formed on the upper electrode 133 of the power device 130. The upper electrode 133 may be an Al layer or an Al alloy layer.

An insulating layer 140 may be formed around the upper electrode 133 on the power device 130. The insulating layer 140 defines a region of the upper electrode 133. When the upper electrode 133 is formed of two electrodes, the insulating layer 140 may be formed between the two electrodes. The insulating layer 140 may be formed of silicon oxide, silicon nitride, or polyimide, and the like.

A protection layer 160 may be formed on sides of the power device 130. The protection layer 160 is formed to surround the sides of the power device 130. The power semiconductor module 100 may include a plurality of power devices 130, and the protection layer 160 may be formed between the power devices 130. The protection layer 160 prevents or inhibits the sides of the power device 130 from being covered by nickel during the formation of the electroless nickel plating layer 150. The protection layer 160 may be formed of polymer resist, silicon oxide, or silicon nitride. When the protection layer 160 is formed of polymer resist, a printing method or a dispensing method may be used. Also, the protection layer 160 formed of a silicon oxide layer or a silicon nitride layer may be formed by an oxygen plasma processing or a nitrogen plasma processing. The protection layer 160 may be removed after the plating is over, if necessary.

The substrate 110 may be a direct bonded copper (DBC) substrate. In FIG. 1, The DBC substrate 110 is depicted. The DBC substrate 110 includes a ceramic layer 111, a first copper layer 113 formed on a lower side of the ceramic layer 111, and a second copper layer 115 formed on the ceramic layer 111. The ceramic layer 111 may be formed of alumina or aluminum nitride for electrical insulation.

The second copper layer 115 is patterned to have a plurality of island parts 115a and 115b. Here, the DBC substrate 110 performs as a power supply to the power device 130 that includes the semiconductor layer 132 and as a path way for dissipating heat generated from the power device 130 to the outside.

The solder layer 120 may be formed by a soldering process or a sintering process. The solder layer 120 may include, Sn, Cu, Ag, Au, Zn, Pb, Bi, or In. In case of the sintering process, the solder layer 120 may be formed by a pressing and heating process using a silver paste or a copper paste.

FIG. 2 is a schematic plan view of the structure of the power semiconductor module 100 of FIG. 1.

In FIG. 2, for convenience of explanation, the two island parts 115a and 115b are depicted. However, the current embodiment is not limited thereto, that is, more than three island parts may be included.

The electroless nickel plating layer 150 and the island part 115b are electrically connected to each other by copper wires 170. The copper wires 170 has a melting point of approximately 1084 oC which is much higher than that of aluminum, and accordingly, there is little change in shape even though the copper wires 170 are used in a power module that is operated at a high temperature.

The copper wires 170 may be formed by disposing copper wires on portions to be connected, and forming a metal-metal bonding between the copper wires 170 and a connection parts by applying ultrasonic energy in a state that a weight is applied to the copper wires 170. The copper wires 170 may have a diameter in a range from about 100 μm to about 500 μm. The copper wires 170 have a heavy wedge bonding type in which a line contact is formed with the electroless nickel plating layer 150 by wedge bonding.

The copper wires 170 have a higher strength than aluminum wires, and thus, a pad of the power device 130 on which the wire bonding is achieved is required to be reinforced. Since the copper wires 170 have a higher strength and higher hardness than the aluminum wires, when the copper wire bonding is performed without the reinforcement of the electrode, a breakage of the power device 130 may occur.

The electroless nickel plating layer 150 is formed for the above reinforcement. The electroless nickel plating layer 150 may be formed by using an electroless plating method on an aluminum pad. The generation of nickel oxide is repressed on the electroless nickel plating layer 150 formed by electroless plating, and accordingly, a copper wire bonding may be performed without using a noble metal, such as Pd, Au, or Ag.

The electroless nickel plating layer 150 increases the strength of the pad for copper wire bonding. The copper wires 170 have a strength and hardness more than two times those of the aluminum wires. Accordingly, when the wire bonding is performed by using the copper wires 170, an additional electrode pad strengthening metallization is required for preventing or inhibiting the power device 130 from damaging by a force and ultrasonic energy that are applied to the power device 130 during the wire bonding.

Also, the electroless nickel plating layer 150 may perform as a barrier for preventing or inhibiting the copper from diffusing into the copper wires 170.

The electroless nickel plating layer 150 is formed as a nano grain or an amorphous layer, and thus, has a higher strength than micro grain nickel. Thus, the pad may be reinforced with a relatively thin layer of the electroless nickel plating layer 150.

The electroless nickel plating layer 150 may have a thickness in a range from about 3 μm to about 30 μm. The thickness of the electroless nickel plating layer 150 may be increased as the diameter of the copper wires 170 is increased. If the electroless nickel plating layer 150 has a thickness less than 3 μm, the reinforcement force to the upper electrode 133 may be weak, and thus, the power device 130 may break during the bonding process of the copper wires 170. If the electroless nickel plating layer 150 has a thickness greater than 30 μm, a warpage may occur in the power device 130, and a manufacturing cost may be increased.

When an electroless nickel plating process is performed on the electroless nickel plating layer 150, an additional adhesion layer is unnecessary due to a desirable adhesion force of Al/Ni.

Also, the electroless nickel plating process that is induced for the reinforcement of an electrode pad of the power device 130 has the following strong points.

First, since the Ni plating layer is formed by using an electroless plating method which is a low cost wet process, a deposition rate is faster than a vacuum Ni deposition process.

Second, when the electroless nickel plating method is used, selective plating only on the electrode of the power device is possible. That is, a lithography process of a Ni layer is very difficult, but the electroless nickel plating does not require an additional lithography process.

Third, the electroless nickel plating includes phosphorus or boron according to a reducing agent, and thus, mechanical properties required by the Ni plating layer may be controlled according to the content of these materials or thermal treatment.

In FIG. 2, there are plural numbers of, for example, eight copper wires 170 are depicted. There is a limit for a single wire to supply a power to a high capacity power device. That is, in case of a power device of 120 KW, four 600V/60 A copper wires are required, and in consideration of safety factor, power may be supplied using eight copper wires.

In the current embodiment, a DBC substrate is used as an example, but the present embodiment is not limited thereto. For example, the substrate may be a lead frame substrate or a printed circuit board (PCB) substrate. A plurality of separated copper patterns may be formed on an upper surface of the PCB substrate, and a power device may be formed on each of the copper patterns or each pattern may be used as an electrode pad. In a lead frame substrate, a plurality of metals is disposed, and the power device is disposed on the metal, and the other metals may be used as electrode pads.

The power device 130 may be one of an MOSFET, an IGBT, and a diode.

When the power device 130 is a diode, one of the lower electrode 131 and the upper electrode 133 is a cathode electrode and the other is an anode electrode.

When the power device 130 is an MOSFET, one of the lower electrode 131 and the upper electrode 133 may include two electrodes. As an example, the lower electrode 131 may be a drain electrode, and the upper electrode 133 may include a source electrode and a gate electrode.

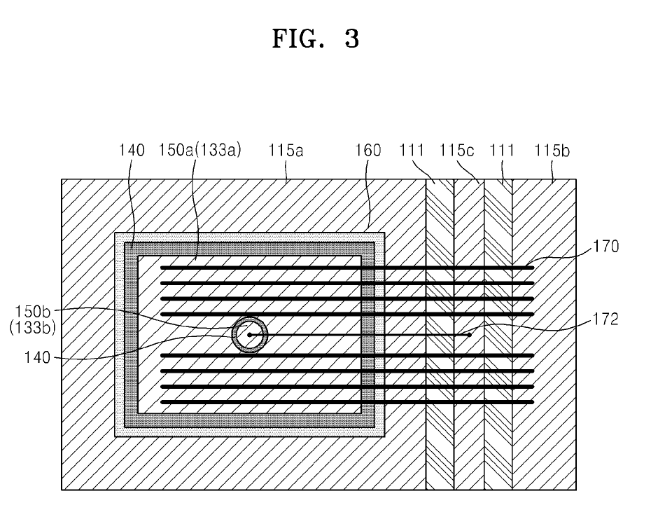

FIG. 3 is a schematic plan view when the power device 130 is an MOSFET. In FIG. 3, like reference numerals are used to indicate substantially the same constituent elements of FIGS. 1 and 2, and the descriptions thereof will be omitted.

Referring to FIG. 3, the upper electrode 133 includes a source electrode 133a and a gate electrode 133b. Nickel plating layers 150a and 150b respectively may be formed on the source electrode 133a and the gate electrode 133b. The nickel plating layers 150a are connected to an island part 115b through eight Cu wires 170. The nickel plating layer 150b may be connected to an island part 115c through an additional wire 172.

When the power device 130 is an IGBT, one of the lower electrode 131 and the upper electrode 133 may include two electrodes. As an example, the lower electrode 131 may be a collector electrode, and the upper electrode 133 may include an emitter electrode and a gate electrode. The connection between the emitter electrode and the gate electrode may be seen from FIG. 3, and thus, the description thereof will be omitted.

In the current embodiment, it is shown that a single power device and an electrode pad are connected via a copper wire, but the present embodiment is not limited thereto. For example, two power devices and an electrode pad may be connected via single copper wire. For example, an electrode on an upper surface of the diode is connected to an upper electrode of the IGBT via single copper wire, and after that, the single copper wire may be connected to an electrode pad on the substrate.

According to the current embodiment, since an electroless nickel plating layer is used as an electrode reinforcement layer, a stable electrical connection may be provided in a high temperature operation power module by using copper wires having a high melting point. Also, manufacturing cost may be reduced since a noble metal layer is unnecessary on the nickel plating layer.

While the inventive concepts have been particularly shown and described with reference to example embodiments thereof, it will be understood by those of ordinary skill in the art that various changes in form and details may be made therein without departing from the spirit and scope of the following claims.

What is claimed is:

1. A power semiconductor module comprising:
a first power device on a substrate;
a first electrode on an upper surface of the first power device;
a first nickel plating layer on the first electrode; and
a copper wire connected to the first nickel plating layer.

2. The power semiconductor module of claim 1, wherein the first electrode is formed of one of aluminum and an aluminum alloy.

3. The power semiconductor module of claim 1, further comprising:
an electrode pad separate from the first power device on the substrate,
wherein the copper wire is connected to the electrode pad.

4. The power semiconductor module of claim 1, wherein the substrate is one of a direct bonded copper (DBC) substrate, a lead frame substrate, and a printed circuit board (PCB).

5. The power semiconductor module of claim 1, wherein the first power device comprises at least one of an metal-oxide-semiconductor field-effect transistor (MOSFET), an insulated gate bipolar transistor (IGBT), and a diode.

6. The power semiconductor module of claim 1, further comprising:
a second power device on the substrate, the second power device including one of an MOSFET, an IGBT, and a diode;
a second electrode on an upper surface of the second power device; and
a second nickel plating layer on the second electrode,
wherein the copper wire connects the first nickel plating layer on the first electrode and the second nickel plating layer on the second electrode.

7. The power semiconductor module of claim 1, wherein the first nickel plating layer has a thickness in a range from about 3 μm to about 30 μm.

8. The power semiconductor module of claim 1, wherein the first nickel plating layer includes one of phosphorus and boron.

9. The power semiconductor module of claim 1, wherein the first nickel plating layer is formed of one of nano grains and an amorphous layer.

10. The power semiconductor module of claim 1, further comprising:
a protection layer surrounding sides of the first power device.

11. The power semiconductor module of claim 10, wherein the protection layer includes one of polymer resist, silicon oxide, and silicon nitride.

12. The power semiconductor module of claim 1, wherein the copper wire has a diameter in a range from about 100 μm to about 500 μm.

13. The power semiconductor module of claim 1, wherein the copper wire forms a line contact with the first nickel plating layer by being connected to the first nickel plating layer using a wedge bonding.
